(19) United States
(12) Patent Application Publication
(10) Pub. No.: US 2018/0002810 A1
(43) Pub. Date: Jan. 4, 2018

(54) Thin film deposition system capable of physical vapor deposition and chemical vapor deposition simultaneously

(71) Applicant: The Regents of the University of California, Oakland, CA (US)

(72) Inventor: Nobuhiko Kobayashi, Sunnyvale, CA (US)

(21) Appl. No.: 15/544,100

(22) PCT Filed: Jan. 20, 2016
(86) PCT No.: PCT/US16/14085

§ 371 Date: Jul. 17, 2017

Related U.S. Application Data
(60) Provisional application No. 62/106,585, filed on Jan. 22, 2015.

(51) Int. Cl. C23C 16/52; C23C 16/34; C23C 16/455; C23C 16/458

(52) U.S. Cl. CPC C23C 16/52; C23C 16/458; C23C 16/34; C23C 16/455

(57) ABSTRACT

A multi-deposition chamber apparatus is provided that includes a first deposition chamber that includes a substrate holder, a retractable sputter gun, a gate valve, an output port, a retractable chamber separator, a gas input port, a gas output port, and an electron cyclotron resonance plasma source, where the retractable chamber separator is configured to selectively segment the first deposition chamber to form a second deposition chamber, where the second deposition chamber comprises the substrate holder, the gas input port, the gas output port and the electron cyclotron resonance plasma source.

### FIELD OF THE INVENTION

The invention relates generally to thin film deposition systems. More particularly, the invention relates to a deposition system for simultaneous Sputtering (SPU) and atomic layer deposition (ALD).

### BACKGROUND OF THE INVENTION

Sputtering (SPU) and atomic layer deposition (ALD)—two prevalent technologies for the deposition of thin films in electronics, optoelectronics, and photonics—exhibit various shortcomings. While SPU is capable of depositing films with a range of chemical compositions without dealing with complex chemical interactions, it lacks accurate and precise control on delivering a small and consistent amount of chemical elements that form a film. In contrast, ALD allows depositing films with accurate and precise control on thickness, however; it lacks explicit tunability of chemical composition. These shortcomings become noticeable, in particular, when a film requires tight thickness control of ˜0.1 nm and spatially varying chemical composition with accuracy and precision of ˜0.1%. Furthermore, the number of chemical elements (e.g. the number of cations in a multi-component oxide thin film) that can be incorporated in a film is generally limited to 5˜7 in SPU and to 2-3 in ALD due to various engineering constrains.

What is needed is a single environment, such as a deposition chamber, in which SPU and ALD operate, enabling “quasi-synchronous processes” of the two deposition modes.

### SUMMARY OF THE INVENTION

To address the needs in the art, a single deposition chamber apparatus having a first deposition mode and a second deposition mode, where the deposition modes are configured to alternate, where the single deposition chamber includes, a substrate holder, a retractable sputter gun, a gate valve, an output port, a retractable chamber separator, a gas input port, a gas output port, and an electron cyclotron resonance plasma source, where the retractable chamber separator is configured to selectively segment the deposition chamber to alternate between the first deposition mode and the second deposition mode, where the second deposition includes the substrate holder, the gas input port, the gas output port and the electron cyclotron resonance plasma source.

According to one aspect of the invention, the retractable sputter gun is configured to retract from the deposition chamber when the retractable chamber separator is deployed to establish the first deposition mode, where the retractable sputter gun is configured to deploy into the single deposition chamber when the retractable chamber separator is retracted from the single deposition chamber. In another aspect, the gate valve is configured to close when the sputter gun is configured to retract from the single deposition chamber, where the gate valve is configured to open when the sputter gun is configured to deploy into the single deposition chamber. In a further aspect, the first deposition mode further includes a sputter gun shutter, where the sputter gun shutter is configured to close when the sputter gun is retracted, where the sputter gun is isolated from the single deposition chamber.

In another aspect of the invention, the gas input port is coupled with the electron cyclotron resonance plasma source.

In yet another aspect of the invention, the deposition mode is configured for a deposition mode that can include chemical vapor deposition, atomic layer deposition, or sputter deposition.

In a further aspect of the invention, the second deposition mode is configured for atomic layer deposition.

According to one aspect of the invention, the substrate holder includes a DC source, an AC source, or DC source and an AC source.

In a further aspect of the invention, the substrate holder is configured to rotate.

In another aspect of the invention, the substrate holder is configured to translate a substrate within the single deposition chamber, and configured to rotate.

### BRIEF DESCRIPTION OF THE DRAWINGS

FIG. 1 shows a drawing of a single deposition chamber that accommodates multiple sputter guns for SPU and a gas injection port with a plasma source for ALD, according to one embodiment of the invention.

FIGS. 2A-2D show FEA of laminar flow in a 2D “pancake” reactor, according to one embodiment of the invention.

FIGS. 3A-3D show FEA of concentration flow in a 2D “pancake” reactor with electric potential, according to one embodiment of the invention.

FIGS. 4A-4B show schematic views of different embodiments of the invention.

FIGS. 5A-5B show normalized ρ maps for two different values of h, according to embodiments of the invention.

FIG. 6 shows the dependence of nonuniformity of normalized ρ on h, according to embodiments of the invention.

FIGS. 7A-7C show normalized ρ maps for different w, according to embodiments of the invention.

FIG. 8 shows the dependence of normalized ρ on w, according to embodiments of the invention.

FIGS. 9A-9C show normalized ρ maps for different hₛ, according to embodiments of the invention.

FIGS. 10A-10B show the dependence of normalized ρ on hₛ along (10A) dx and (10B) dy, according to embodiments of the invention.

FIGS. 11A-11G show FEA of charged particle flow under the influence of electric potential, according to one embodiment of the invention.

### DETAILED DESCRIPTION

The current invention brings provides sputtering (SPU) and atomic layer deposition (ALD) in a single deposition chamber, where these distinguishable features are not found in conventional stand-alone SPU or ALD, or in unoriginal cluster tools built upon SPU and ALD. According to the current invention, SPU and ALD operate in a single environment, which is referred to herein as “SAS”, allowing “quasi-synchronous processes” of the two deposition modes. In one embodiment, high-speed rotating substrate stage (HSRSS) with a rotation speed up to 200 r.p.m. are provided to enable the deposition of films that contain vast numbers of chemical elements. According to the current invention, SAS with a HSRSS (SAS-HSRSS) are enabled by the distinct innovation of SPU and ALD being geometrically coupled, providing fast-switching between SPU and ALD so that the two deposition modes continue complementary. Furthermore, SAS-HSRSS will enables fabrication of multi-component alloy (MCA) films at the level of structural complexity that has never been reached.

In a further embodiment, the SPU and ALD are unified in a single vacuum housing in which a substrate sits on a stage that spins at a high rotation rate. Since SPU and ALD processes are fundamentally incompatible to each other, a key innovation of the invention is the development of a mechanism by which two deposition environments created for SPU and ALD are switched back and forth. In addition, commercial SPU and ALD merely offer deposition environments established as “standard”. In contrast, SAS offers distinctive deposition environments by featuring an additional control, electric potential of a substrate in a reaction chamber. Adjusting the electric potential of a substrate in SAS explicitly controls the kinetics of reaction species in the vapor phase and on the substrate surface to dynamically engineer physical properties of thin films by controlling respective micro structures.

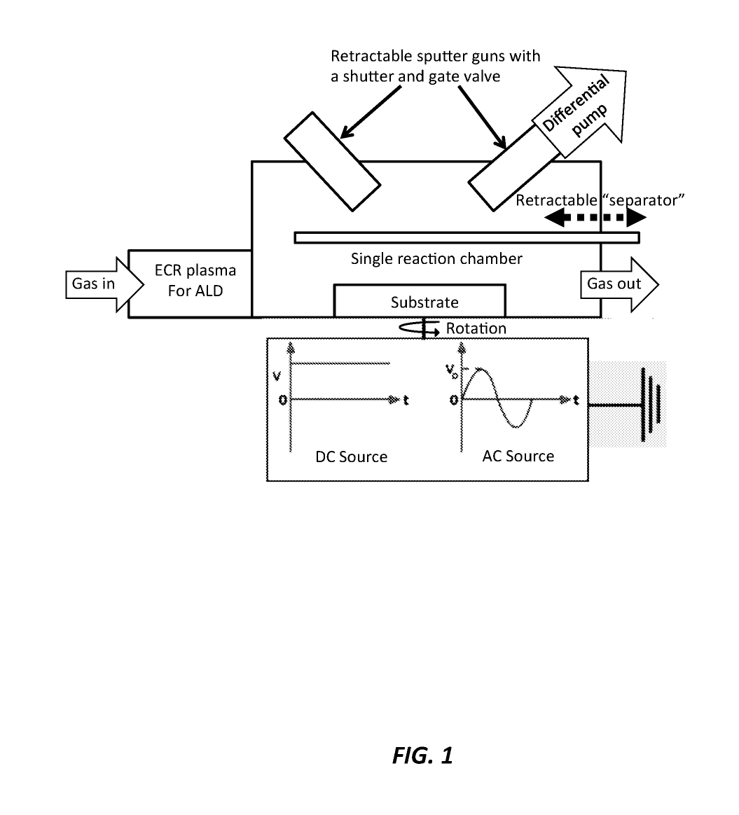

FIG. 1 shows, one embodiment of a single deposition chamber apparatus that allows a first deposition mode to be established by having a substrate holder, a retractable sputter gun, a gate valve, an output port, a retractable chamber separator, a gas input port, a gas output port, and an electron cyclotron resonance plasma source, where the retractable chamber separator is configured to selectively segment the deposition environment to establish a second deposition mode with the substrate holder, the gas input port, the gas output port and the electron cyclotron resonance plasma source.

In one embodiment, the retractable sputter gun is configured to retract from the deposition chamber when the retractable chamber separator is deployed to establish the second deposition mode, where the retractable sputter gun is configured to deploy into the deposition chamber when the retractable chamber separator is retracted from the deposition chamber. Here, the gate valve is configured to close when the sputter gun is configured to retract from the deposition chamber, where the gate valve is configured to open when the to sputter gun is configured to deploy into the deposition chamber. Further, the first deposition mode is established with a sputter gun shutter, where the sputter gun shutter is configured to close when the sputter gun is retracted, where the sputter gun is isolated from the deposition chamber.

In another embodiment, the gas input port is coupled with an electron cyclotron resonance plasma source.

In further embodiments of the invention, the deposition mode allows chemical vapor deposition, ALD, or SPU, where the second deposition mode allows ALD.

In another aspect of the invention, the substrate holder includes a DC source, an AC source, or DC source and an AC source. Further, the substrate holder is configured to rotate.

According to one embodiment, a chamber is provided that accommodates multiple sputter guns for SPU (only 2 sputter guns are shown in the FIG. 1) and a gas injection port with a plasma source for ALD. The substrate is biased by either DC or AC voltage, setting the substrate at a certain electric potential with respect to, for instance, the system ground potential to adjust kinetic energy of ions and any charged particles in the vapor phase in the chamber as well as, to some extent, those on the substrate surface. The substrate bias offers an additional parameter in addition to conventional deposition parameters (e.g. substrate temperature, gas flow rate) to explicitly control microstructures of a thin film.

In one embodiment, a sputter gun is “retracted” and isolated by a fast-acting gate valve to minimize disturbance to a laminar flow running between the gas in to the gas out and also minimize cross-contamination associated with ALD processes. Furthermore, the deposition chamber is “divided” into two sections by a separator to switch back and forth between SPU and ALD.

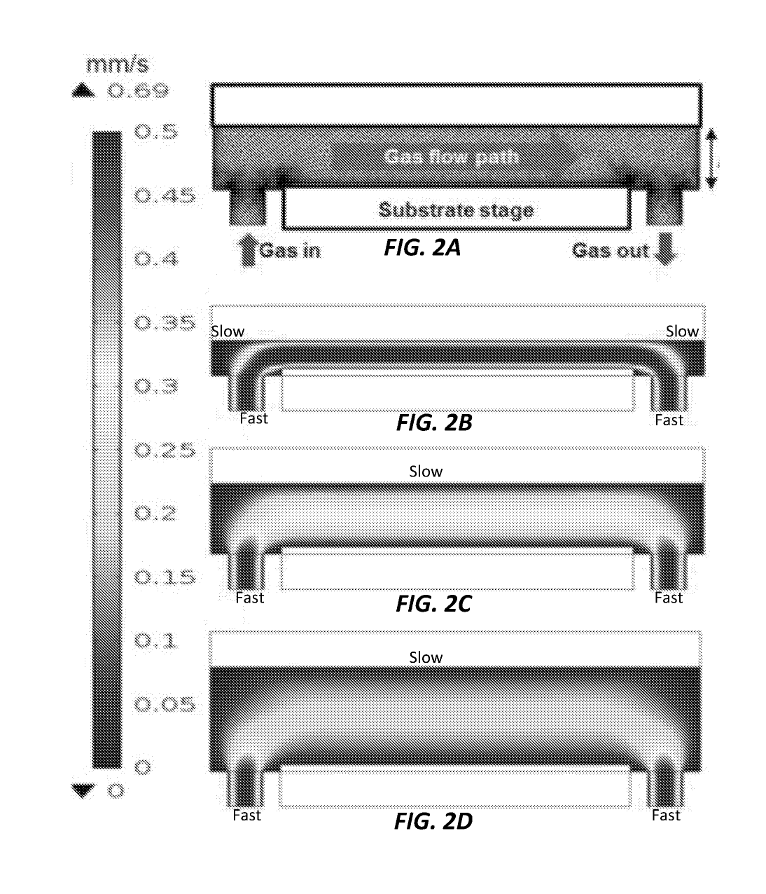

Finite-Element-Analysis (FEA) on gas flow and the dependence of the motion of flowing charged species on electric potential, where a 2D “pancake” reaction chamber (diameter 80 mm) was analyzed in FIGS. 2A-2D to show how a steady-state laminar flow is influenced by the height h that determines the 2D cross section of the gas flow. Shown in FIG. 2A is a mesh used for the FEA. The boundary conditions are as follows: the mass flow rate of nitrogen at the gas inlet was fixed to 20 sccm and the pressure at the gas outlet was fixed to 10 Torr. In FIGS. 2B-2D, the leftward chart represents gas velocity mm/s, indicating that the laminar flow can be maintained even when h is 15 mm, however the gas velocity drops dramatically, which certainly influences how deposition precursors diffuse from the center of the laminar flow toward the substrate. This is consistent with the fact that the ALD has h ˜10 mm.

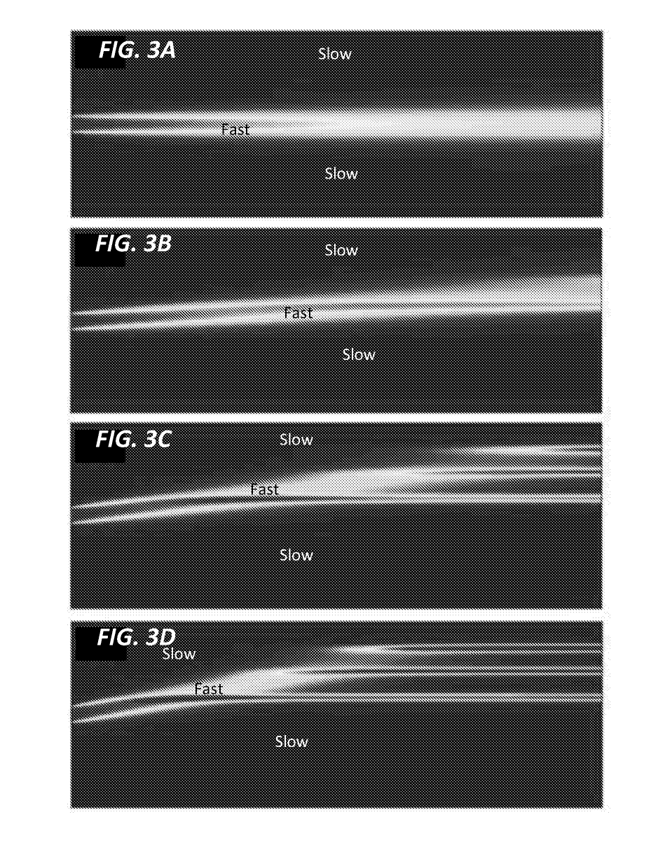

FIGS. 3A-3D display the influence of static electric field to the motion of charged particles in a laminar flow. The laminar flow runs through a small chamber (3 mm×10 mm) from left to right while the electric potential (i.e. electric field) is applied perpendicular to the flow. The leftward chart represents the concentration of three types of species contained in the flow. The three types of species are charged at three different levels. When V=0V in (FIG. 3A), the concentration flow appears to “flow” with the laminar flow, however, as V increases; (FIG. 3B) 20V, (FIG. 3C) 40V, and (FIG. 3D) 60V, the concentration flow splits into three paths, indicating the emergence of “dielectrophoresis” type of phenomenon. This “trick” could be used to force a laminar flow to “effectively” stay closer to a substrate even though the chamber height is much larger than that would be usually required for ALD.

Costmary SPU and ALD are separately designed, built and operated (i.e. stand-alone SPU or ALD) mainly because of their inherent incompatibilities. SPU and ALD come with their proven advantages; SPU offers flexible control on chemical composition while ALD offers superior control on thickness and smooth surface morphology. To take advantages of both SPU and ALD, stand-alone SPU and ALD can be integrated as a usual cluster tool in which, in principle, a substrate can be transferred back-and-forth between two reaction chambers to deposit a stack of multiple films in a sequential manner (i.e. SPU and ALD still operate as a stand-alone system). However, in such a sequential process in a cluster tool, contamination at interfaces becomes an unavoidable issue for many of devices required for the proposed research activities because the device performance critically depends on the nature of interfaces and surfaces. In addition, many types of films cannot be simply deposited by a sequential process offered by a stand-alone or a cluster tool. For instance, a 100 nm thick dielectric-metal composite film deposited by repeating a cycle of aluminum oxide ALD (i.e. a ˜0.12 nm thick aluminum oxide) followed by is of platinum SPU (i.e. a ˜0.5 nm thick platinum) would require impractical 160 times of sample transfers between SPU and ALD in a cluster tool, which would also result in the introduction of significant accumulative contamination. Another example would be a 10 nm thick metal oxide film in which a large number of different cations need to be uniformly distributed for the study of the dependence of film properties on high-level structural complexity. Currently, SPU tools built on conventional design concepts hardly offer co-deposition of even 5 SPU targets limiting the number of elements to 5 if each target is made of a single element. Multiple alloy targets each of which contains 2 or more elements at a pre-fixed composition can be used, however, this arrangement makes it almost impossible to produce systematic films with hundreds of variations in composition or films with varying composition along thickness.

The current invention allows co-deposition of at most 16 SPU targets taking full advantage of both SPU and ALD and offering capabilities of strictly controlling composition and thickness simultaneously with a flexible adjustability of deposition environment. The current invention enables both SPU and ALD to operate “quasi-simultaneously” and “complementary” in a single environment. The current invention further offers distinctive deposition environments by featuring an additional control—electric potential applied to a substrate. The current invention enables adjusting electric potential of a substrate to explicitly control kinetics of reaction species in the vapor phase as well as on the substrate surface to dynamically engineer physical properties of films by controlling respective micro structures.

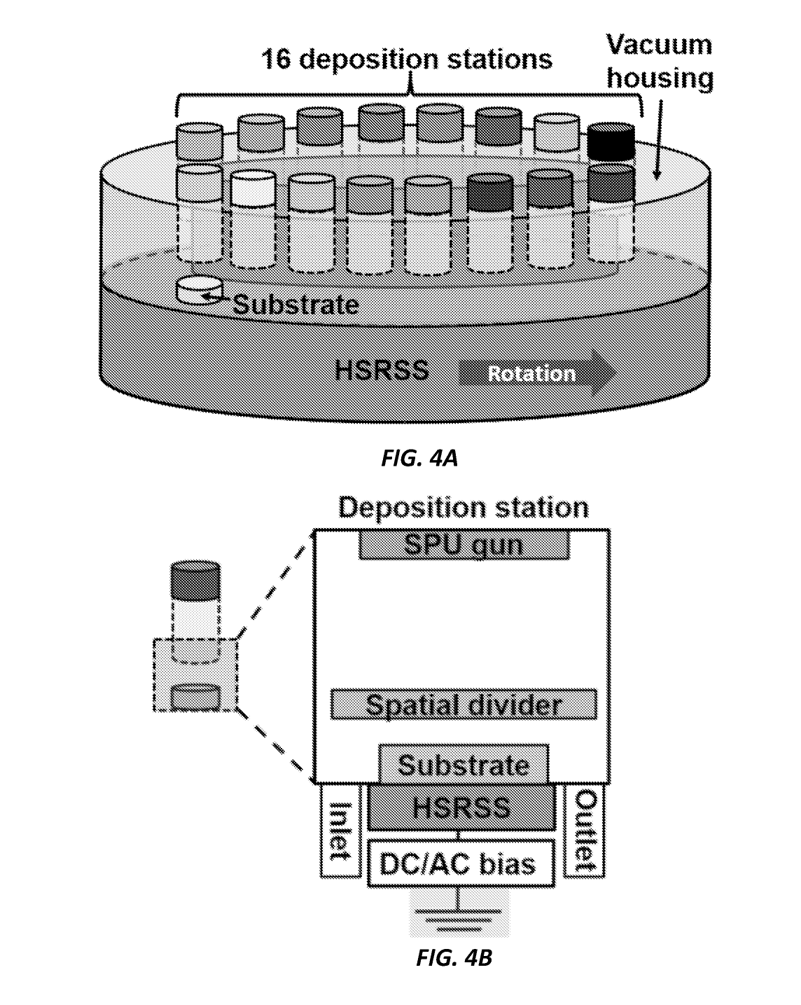

FIGS. 4A-4B show (4A) a schematic drawing of the invention equipped with 16 deposition stations each of them has basic configuration similar to the deposition chamber shown in

FIG. 1 arranged in a circle and built with a HSRSS that turns and brings a substrate to any of the 16 deposition stations (Note: the number “16” is merely an example not a limitation), which are all housed in a vacuum housing. The HSRSS can also continuously spin so that the substrate repeatedly visit all of the 16 deposition stations one by one. At any period of time during a deposition process, either all 16 SPU guns or selected SPU guns are energized. The role played by a HSRSS is critical in controlling atomistic fraction of an element in a SPU process by the current invention. Because the rotation speed determines a time period during which a substrate stays in a specific deposition station, the current invention enables variable rotation speeds of the substrate, where deposition having a high-speed rotating substrate stage that turns at ˜1000 r.p.m. is within the scope of the current invention. For example, for a stage with a radius of 22.5 cm, which translates into the angular momentum L˜5.3M m²/s (M: mass). Such a rotating substrate stage for current invention with 16 SPU guns, assuming that a single SPU gun sits on a Φ6 inch CF flange, we will be able to have a rotation speed up to ˜230 r.p.m. by maintaining the comparable L. This further suggests that, given the deposition rate of 0.01-0.03 nm/kW/s obtained from our preliminary results for various binary metal oxides, 0.0008 nm/revolution are achievable for each deposition station in SPU mode. If aluminum (Al) is used as an example, the rotation speed of 230 r.m.p. would offer a SPU deposition rate of ˜5×10¹² atoms/revolution/cm² on a f c.c. Al(001) plane with surface atomic density ˜1.2×15 cm², suggesting that compositional control of atomistic fraction ˜0.4% is feasible—one of many features of the current invention that conventional SPU cannot match.

FIG. 4B reveals details of a single deposition station having the following four main components: (1) SPU gun with a selected element, (2) Spatial divider, (3) DC/AC substrate biasing, and (4) ALD precursor inlet/outlet, for example, the smallest SPU guns commercially available (e.g. Φ1 inch SPU gun: HVMSS-SPC-1 by MTI Corporation) occupy 16 exemplary stations, setting the maximum size of a substrate to be ˜4 cm². In another example, the deposition rate needs to be in the range of 0.01-0.03 nm/kW/s for various binary metal oxide films suggesting that RF power density of ˜6 W/cm² is required. A Φ1 inch SPU gun by MTI Corporation that supports RF power of ˜100 W will certainly cover this power density requirement. As illustrated in FIG. 4B, SPU and ALD environments in a deposition station are uniquely isolated by a fast-acting pneumatic “spatial divider”. The spatial divider can be inserted into or retracted from a deposition station within 1 s without breaking vacuum, creating environments suitable for either SPU or ALD and minimizing cross-contamination associated with these two incompatible deposition modes. When the spatial divider is retracted, SPU mode is activated, and ALD mode is activated by inserting the spatial divider and ALD precursors are injected/evacuated via the inlet and outlet. As shown in FIG. 4B, the substrate is biased by either DC (e.g. ˜1000 V) or AC voltage (e.g. ˜500 Vp-p), setting the substrate to a specific electric potential with respect to the system ground to adjust kinetic energy of charged species present in the vapor phase. The substrate bias offers another tuning knob in addition to usual deposition parameters (e.g. substrate temperature, gas flow rate) in both SPU and ALD to explicitly control microstructures of the films.

Another unique feature in controlling composition, by the current invention, is seen in the following example. A monolayer (e.g. ˜0.1 nm thick) of ABₓ alloy film is initially deposited by ALD with a stoichiometric composition (e.g. x=2). If an ABx (x<2) film is desired, and then a controlled amount of “excess” A element is deposited by SPU, taking advantage of HSRSS, to drive AB2 into AB2−y (y<2). Alternatively, if an ABₓ (x>2) film is required, and then a controlled amount of “excess” B element is added by SPU to drive AB₂ into AB_{2+y} (Note: appropriate in-situ heat treatment would be required for these processes. The current invention enables “in-situ” tuning of surface composition (i.e. surface defect engineering) at monolayer level without substantially altering a given thickness, which cannot be done by stand-alone SPU or ALD, or even by a cluster tool if the required total thickness is large (e.g. 100 nm). Table 1 summarizes other key specifications of embodiments of the current invention.

TABLE 1
Key specifications of SAS system

| | | |
|---|---|---|
| SPU capability | SPU guns | At most 16 SPU guns can |
| | | participate in deposition at the |
| | | same time |
| | SPU modes | RF, DC, or pulsed-DC |
| | HSRSS | Rotating substrate stage that |
| | | spins at up to 200 [r.p.m.], |
| | | spin-SPU |
| ALD capability | Metal precursors | Al, Si, Ti, V, Cr, Co, Zn, Ga, Y, |
| | | Zr, Nb, Mo, Ru, Hf, Ta, W, Pt |
| | non-metal | Water and ozone |
| | precursors | |
| | Extra energy source | Remote plasma |
| Common | Substrate bias | AC or floating DC |
| | Substrate heater | Maximum temp |
| | | ~1000 [degrees C.], up to |
| | | 4 [cm²] substrate |

2-dimensional computational fluid dynamics combined with finite-element-analysis (CFD-FEA) are provided to demonstrate key aspects of the current invention, where examples are provided for the following three aspects of a single deposition station: (1) SPU deposition uniformity over a substrate, (2) Spatial divider width, and (3) Spatial divider height. Table 2 summarizes key parameters in CFD-FEA.

TABLE 2
Key parameters in CFD-FEA of a single deposition station.

| Parameter | Quantity |
|---|---|
| Chamber width | 70 [mm] (The minimum linear size to |
| | accommodate a φ1° diameter SPU gun) |
| Chamber height (h) | h = 10-120 [mm] (Variable) |
| Spatial divider thickness, | 2 [mm], hₛ = 10-30 [mm] above |
| location (hₛ) | the substrate (variable) |
| Spatial divider width (w) | w = 10-90[%] of the chamber |
| | width (Variable) |
| SPU target width | 26 [mm] |
| Heater width | 30 [mm] |
| Substrate width | 20 [mm] |
| PVD gas type, pressure | Gas type: argon at 300 [K], |
| | Gas pressure: 1 × 10⁻³ [Torr] |
| ALD gas inlet and outlet width | 5 [mm] |
| ALD inlet characteristics | Gas type: nitrogen at 300 [K], Inlet |
| | pressure: 760 [Torr], Mass |
| | flow: 20 [sccm] |
| ALD outlet characteristics | Outlet pressure: 1 × 10⁻³ [Torr] |

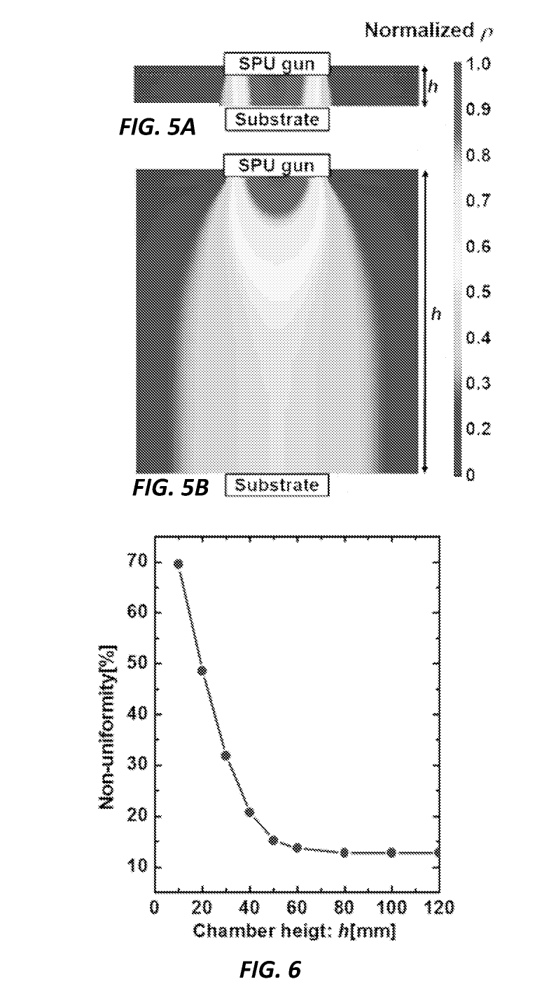

In the current example using relatively small (Φ1″ diameter) SPU guns, it is important to ensure optimum uniformity in the density of deposition species (r) coming from a SPU target and landing a substrate. FIGS. 5A-5B illustrate two maps showing the distribution of normalized ρ, (ρₙ) in two deposition stations having two different h (chamber height): (5A) 10 mm and (5B) 80 mm indicating h significantly influences the distribution of ρₙ across the substrate. FIG. 6 shows the dependence of nonuniformity defined as: (the maximum ρₙ—the minimum ρₙ)/the minimum ρₙ across the substrate clearly suggesting that h needs to be at least 60 mm to minimize non-uniformity although h=10 mm would be more appropriate for ALD to maintain a laminar flow between the inlet and outlet.

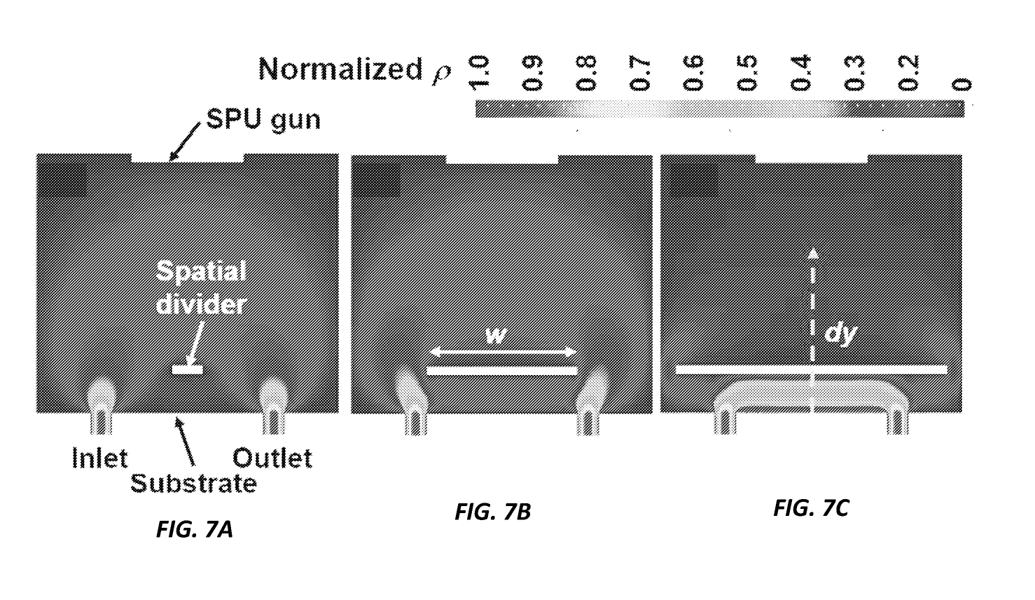

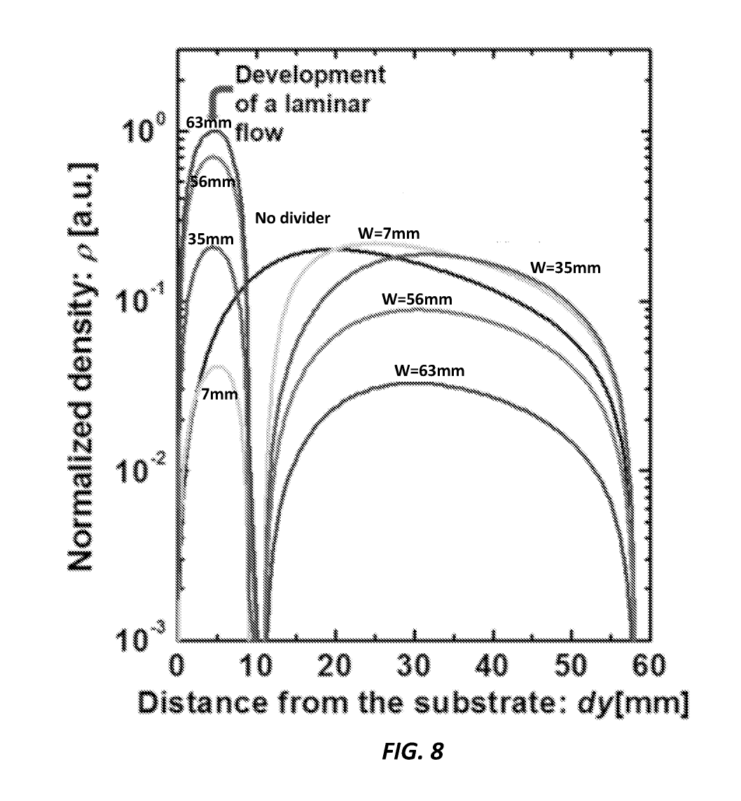

In one embodiment, since SPU and ALD co-exist in a deposition station, it is critical to ensure that a spatial divider creates deposition environment appropriate for ALD for the optimum h obtained as described above. In this example, for ALD, a laminar flow needs to be maintained above the substrate for h in the range of 60 mm, which is much larger than that normally found in conventional ALD tools. The current invention resolves this issue using a spatial divider, driven pneumatically, that is inserted into or retracted from the deposition station within a time period less than 1 sec. without breaking vacuum. FIGS. 7A-7C show three maps displaying the distribution of ρₙ in ALD mode for three different w (spatial divider width): (7A) 7 mm, (7B) 35 mm, and (7C) 63 mm of a spatial divider located at 10 mm above the substrate, suggesting that a laminar flow would be established in (7C). FIG. 8 shows the dependence of ρₙ along the dotted line (dy) perpendicular to the substrate as in FIG. 7C, indicating the progressive development of a laminar flow as w increases; it shows that w needs to be 90% of the chamber width for this specific inlet/outlet distance.

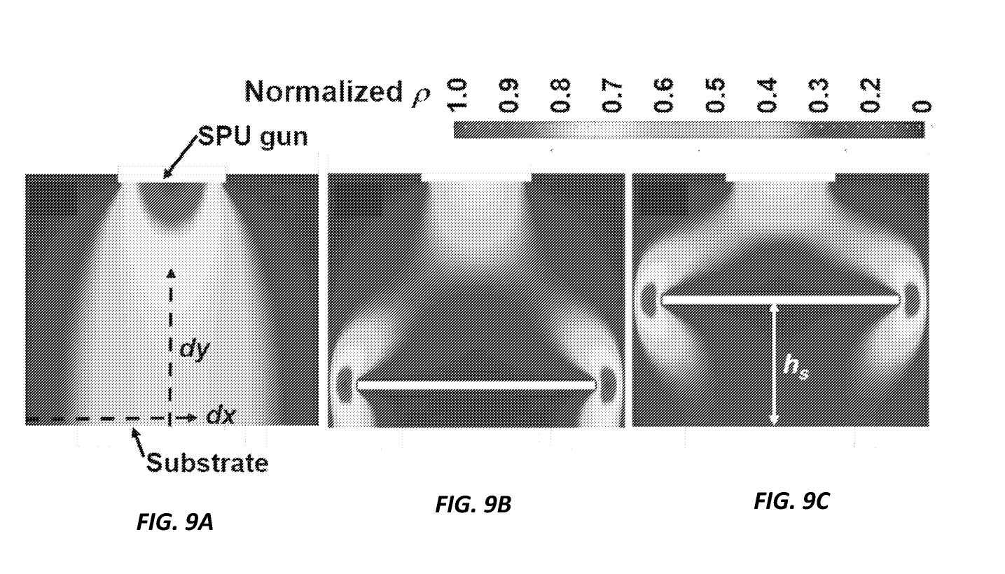

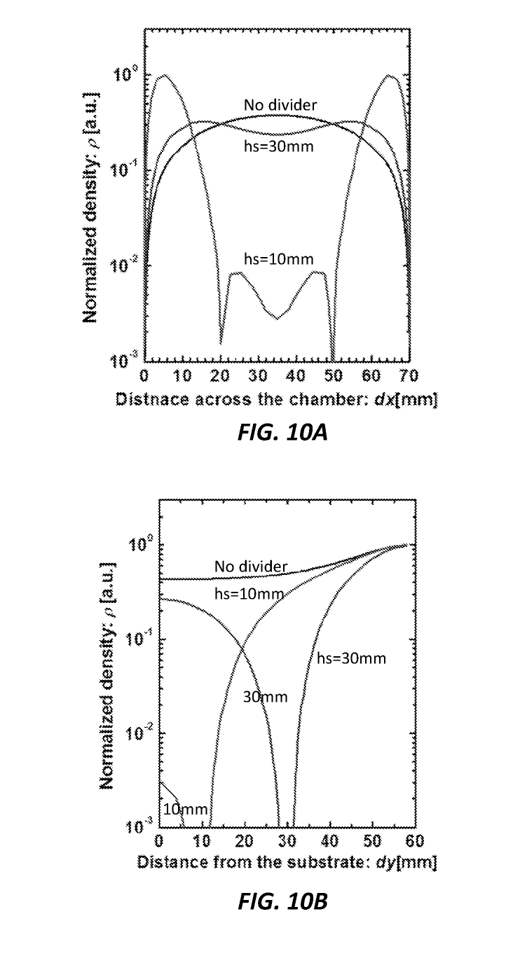

During a long ALD period, the respective SPU gun can be turned off, however; it is worth evaluating if a spatial divider effectively blocks SPU species and creates a laminar flow simultaneously for a short ALD period. FIGS. 9A-9C show three maps displaying the distribution of rₙ in SPU mode for three different hs (locations of the spatial divider): (9A) No spatial divider, (9B) hₛ=10 mm, and (9C) hₛ=50 mm. FIGS. 10A-10B show ρₙ plotted across the bottom of the chamber (dx) and along dy, respectively as defined in FIG. 9A, indicating that a spatial divider with w=80 mm placed at hₛ=10 mm would effectively block SPU species while it creates a laminar flow. When hₛ=30 mm, SPU species appears to leak through the gap between the spatial divider and the chamber wall.

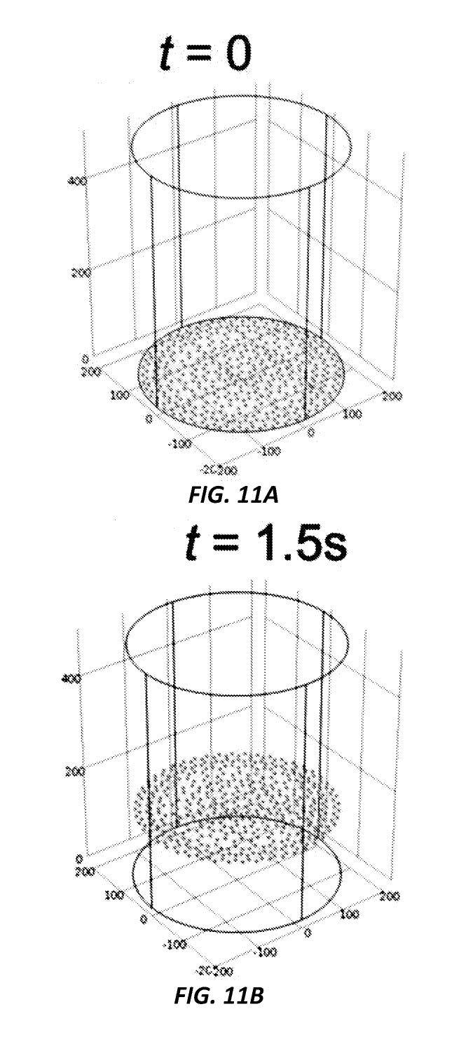

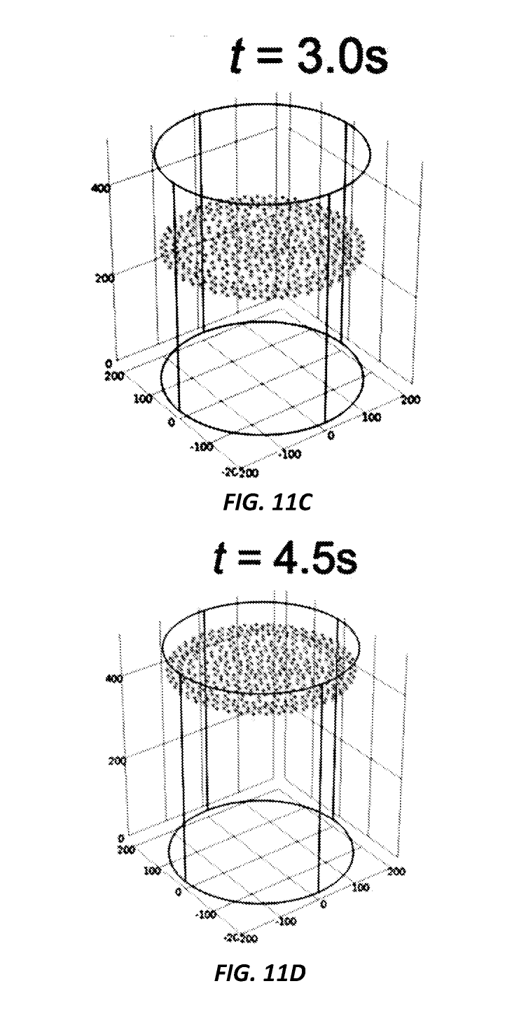

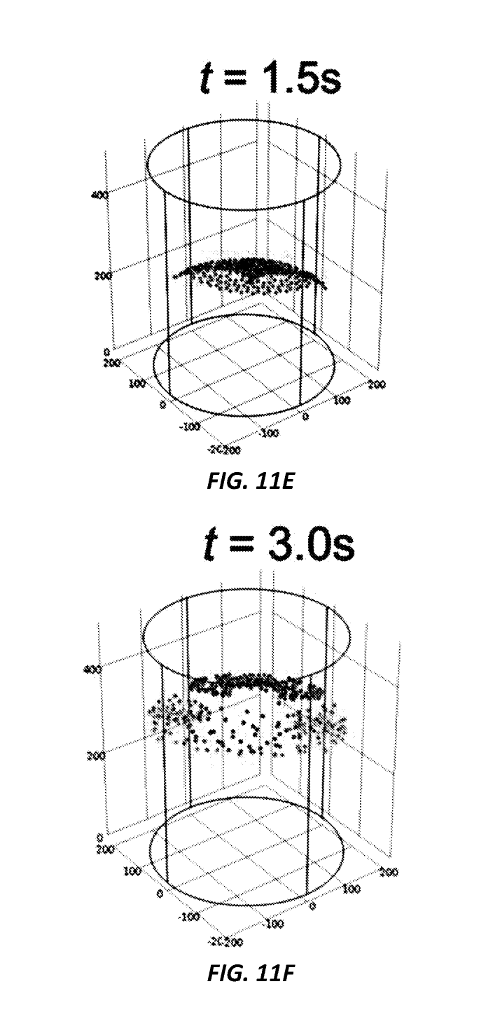

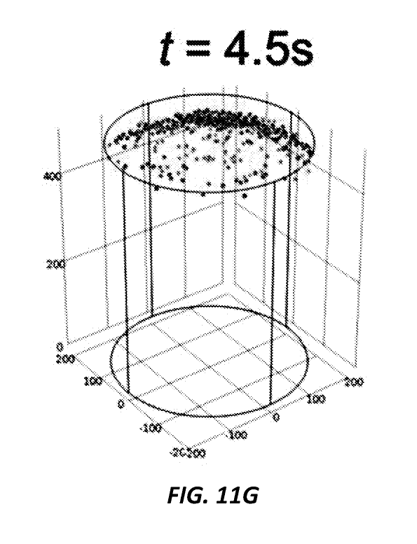

Even though steady-state 2D FEA provides a lot of useful guidance, 3D dynamic FEA would be also unavoidable to draw more accurate pictures. FIGS. 11A-11G present the influence of static electric potential to the motion of charged particles calculated as time elapsed from t=0 to 4.5 s. The particles were launched from the bottom of the cylinder (diameter 40 mm) with certain initial velocity in z-direction (i.e. the direction in parallel to the cylinder's long axis). Elastic particle-particle interaction and elastic particle-wall (of the cylinder) interactions were assumed. Electric potential was applied in x and y directions (i.e. the directions parallel to the diameter of the cylinder) in FIGS. 11E-11G while electric potential was zero in FIGS. 11B-11D. Clearly, the electric potential influences overall motion of the particle, as a result, the spatial distribution of the particles on the top (e.g. substrate) appears to be completely different in the two cases.

According to the current invention, both SPU and ALD operate, sequentially or simultaneously (i.e. Quasi co-deposition-mode). Clearly seen in the discussion above, SAS is a well-integrated single instrument

Further, an ideal crystalline compound built with a definite translational symmetry allows no variability of composition when a distinct crystal structure is assigned, which is the foundation of stoichiometric compounds. Many studies have unveiled, however, the existence of various non-stoichiometric compounds (NSC) that exhibit variations in composition with no apparent modification in their crystal structures. Many NSC exhibit properties that drastically change when a subtle compositional variation is introduced, suggesting that detailed tailoring of composition is critical for systematic studies of NSC, especially in the form of thin film. A NSC thin film with a specific composition may or to may not be thermodynamically stable, but unstable compositions may be kinetically stabilized in the form of thin film.

NSC, in particular NSC of metal oxides, have been extensively studied from various perspectives, including high-temperature superconductors (HTSC) in which small variations in oxygen content appear to have significant impacts on their physical properties. Endless possibilities of combining different elements on the Periodic Table have been well perceived in developing such multi-component alloys (MCAs), yet, exploration of such possibilities seems to be never-ending. Regardless of recent advancement on computing power, predicting even basic features such as composition and crystal structure of a new solid is fundamentally impossible because composition and crystal structure are often two input parameters to calculate properties of a material; thus a new material is repeatedly “discovered” experimentally. While a large number of substances that have been discovered are molecular organic compounds made of only few elements (e.g. carbon, hydrogen, oxygen, nitrogen), a small number of inorganic compounds can contain a variety of elements—a fascinating character of MCA and the core motivation of the current invention.

The current invention is well suited for exemplary applications that include resistive switching devices (RSDs) and optical waveguide concentrators (OWCs). Utilizing RSDs has become one of the promising options for future computing systems. Fabrication of RSDs built on multiple dielectric and metallic films with thickness in the range of 1-8 nm requires both SPU and ALD to achieve reproducible and predictable device characteristics. A conventional stand-alone ALD system and a stand-alone SPU system, or a cluster tool that has ALD and SPU systems integrated through a vacuum tunnel operating in separate chambers results in undesirable surface oxidation, unpredictable surface contamination. Moreover, electrical performance of RSDs is drastically improved by seamlessly combining the two methods and by explicitly controlling composition, microstructures, and thickness of the films simultaneously, which are enabled by the current invention.

OWCs, made of multiple dielectric films, are passive optical devices that concentrate guided light with minimum transmission losses however, the deposition of dielectric films, the most critical part, largely relies upon SPU tools housed at various industrial partners. Adjusting substrate electrical potential during SPU is critical to simultaneously obtain high refractive index and low extinction coefficient by establishing amorphous phases. One embodiment of the current invention enables real-time substrate electrical potential adjustment during SPU.

A further application of the current invention includes the fabrication of silver-based mirror coatings that can withstand observatory environments for several (5-10) years before recoating is needed. In the past, recoating mirrors involved major cost and risk on large telescopes such as the W. M. Keck telescopes, having 36 primary mirror segments each, and the Thirty-Meter Telescope, having 492 mirror segments. While bare aluminum has been the standard telescope mirror coating, protected silver-based coatings enabled by the current invention can provide ˜10% reflection gain per surface, or ˜30% gain in a modern 3-mirror telescope, and ˜⅓ the emissivity in the thermal IR. ALD-deposited barrier layers obtained by the current invention show significant improvement in durability of silver-based coatings with excellent UV/blue response. In another example, the Gemini telescope mirrors use the only successful astronomical silver-based coating, but the blue reflectivity is poor. Scaling-up ALD mirror coatings up to meter-class sizes is achieved by the current invention, where all layers are deposited by SPU, then ALD in the same chamber for the final barrier layer eliminates contamination between the layers.

In a further exemplary application, optofluidics utilizes two types of waveguides: hollow-core waveguides (HCWs) and solid-core waveguides (SCWs). Chip-scale HCWs based on anti-resonant reflecting optical waveguides for on-chip integration of non-solid materials (i.e. liquids and gases), continue to receive interest for many applications, such as slowing light on a chip and rapid infectious disease detection. The platform interfaces solid-core ridge waveguides with hollow-core ARROW waveguides that can guide light and fluids through micronscale channels. A small excitation volume is defined by the solid-core waveguide intersecting the hollow channel. Generated signals are captured and guided through the channel to the edge of the chip. This arrangement has been used to detect single viruses, nucleic acids, nanobeads, and other particles. While the current performance is excellent, advancement to detection of a single molecular beacon, for instance, is limited by the present fabrication method using Plasma Assisted Chemical Vapor Deposition (PECVD) of dielectric layers around a sacrificial core. PECVD is simply not suitable, as a result the vertical layers are significantly thinner than those deposited horizontally, leading the formation of crevices that causes vertical mode displacement and coupling loss between liquid and solid-core waveguides. The current invention flawlessly combines ALD and SPU and provides films with ultimate uniformity and conformality, significantly improving the device performance.

In addition to HCWs and SCWs, the basis of integrated optical devices used in optical data communications, provide interfaces to HCWs. A further embodiment of the current invention provides continuous tunability of material composition that enables the fabrication of novel waveguide structures via (i) tight optical confinement using the high index contrast afforded by titanium alloys; (ii) low propagation loss by using high quality films deposited with optimized fabrication parameters; and (iii) the ability to design and implement graded index (GRIN) profiles using ternary material combinations.

In a further embodiment, the SAS combined with the advanced nanopatterning capabilities enables new novel nanomagnetic structures for fundamental research and spintronic applications. In addition to sputtering of metals, SAS is useful for creating mixed metal-oxide-based spin transfer torque magnetic RAM (STT-MRAM) structures that require both SPU and ALD. This structure based on CoFeB—MgO—CoFeB forms the basis of spin transfer torque magnetic memory that requires tight control on thickness (˜1 nm) and composition.

The current invention further provides the realization of nanoplasmonic devices enabling ultrasensitive detection of biomarkers from circulating tumor cells (CTCs). CTCs constitute an important pathway for metastasis to vital distant organs, a mechanism that is responsible for the vast majority of cancer-related deaths. The ability to probe viability of extraordinarily rare CTCs has profound implications in prognosis and theranostics of cancer and development of new drugs. The ability to monitor extremely low-level biomolecules is hindered by the competition of two fundamental physical processes occurring on metallic surfaces. While enhanced local optical density of states (LDOS) on metal surfaces offers enhanced fluorescence excitation and emission of the quantum emitters, strong coupling of fluorophores to metals also causes fluorescence quenching due to enhanced non-radiative losses, where reliable control of these two competing processes has not been successful. To achieve reliable control, the current invention provides precise controlling of the radiative and non-radiative coupling of fluorophores to metal surfaces using ultrathin dielectric oxides, where features down to 100 nm that use very thin (<8 nm) and uniform oxide layers (<1 nm) are needed to precisely control the LDOS and the flow of light out of the emitter to the far-field detectors with minimal non-radiative losses. The ultra-precise and uniform deposition capability of the current invention allows one to fabricate fine-tuned plasmonic devices over-large areas and achieve ultrasensitive fluorescence measurements at single molecule levels and analysis of extraordinarily rare CTCs at single cell levels.

Ultrathin nonstoichiometric transition metal oxides represent a class of materials known as mixed electronic ionic conductors (MEICs). One major example of a device based on such materials is a memristor based on the drift of oxygen vacancies in an applied electronic field. Depending on the concentration (0.5-3.0%) and distribution (1.0-3.0 nm layers) of vacancies, which act as dopants in a thin insulating film, the electrical resistance of the film can be tuned over six orders of magnitude, but once the field is switched off the resistance of the film is stable for decades. This property makes these devices extremely interesting for storing both digital and analog information, as well as for uses as configuration bits in field programmable electronic circuits and artificial synapses in neuromorphic systems. However, in order to obtain reproducible, uniform and predictable results requires exquisite control over the concentration profile of oxygen vacancies in a thin oxide film. Another type of device is a threshold switch, or current-controlled negative differential resistance element, that operates via a phase transition from a Mott insulator to a metallic state as current is injected into the device. The properties of such devices can be tuned over a wide range by controlling the anion to cation ratio in the material. Commercial deposition systems are incapable of providing such control, since ALD systems are designed to deposit to only stoichiometric films over a wide range of operating conditions and SPU requires the manufacture of a target with an exact stoichiometry, which is essentially impossible to control at the scale needed. Thus, the current invention enables a thin stoichiometric film to be deposited as the tunnel barrier for the device, and a precise amount of metal can then be sputtered on top of the thin film without transferring samples or breaking vacuum to provide the needed change in stoichiometry—heating of the sample transforms the excess of metal into the desired amount of vacancies, and a multilayer system can be grown if necessary.

Among inorganic compounds, many binary compounds appear to have simple stoichiometric compositions (i.e. phase): AB AB₂, AB₃ or A₃B₅₂₉ where A and B represent two elements in the alloys. The quandry of having multiple complex phases when the number of elements is increased seems to be alleviated by the observation that the high mixing entropy in an alloy that contains multiple elements “forces” the alloy to form a small number of rather simple phases leading to the prevalent term “high entropy alloy”. High-entropy alloys (HEAs), are often referred to as those containing 5 or more principal elements with a concentration in the range of 5-35 at %. The idea is that the driving force that produces multinary phases generally becomes smaller as the number of elements increases although these multi-component alloys do not necessarily possess unusually high mixing entropy or high configurational entropy. To explain the rationale here, if the copper oxide-based high-temperature superconductors are used as a guide, it becomes evident that the transition temperature (Tc) is ˜40K when three elements were present (e.g. La₂CuO₄), over 90K when four elements are present (e.g. YBa₂Cu₃O₇), ˜130K when five elements are present (e.g. Tl₂Ba₂Ca₂Cu₃O₇), and even ˜165K under pressure in HgBa₂Ca₂Cu₃Ox. Nevertheless, it is true that there have been a growing number of studies of multicomponent and high entropy alloys with the hope of discovering new materials by implementing this particular strategy.

While reactive SPU is the choice for depositing nitride (e.g. Fe—Co—Ni—Cr—Cu—Al—Mn and Fe—Co—Ni—Cr—Cu—Al_{0.5}), oxide (e.g. AlxCoCrCuFeNi), and intermetallic MCAs, many experiments indeed were done with synthesis techniques such as arc casting suitable for making bulk materials. Since conventional reactive SPU comes with a restriction on the number of SPU targets that can be used simultaneously, a single target often needs to contain desired elements with a specific mole fraction, in other words, obtaining MCAs with varying composition requires different SPU targets, and thus, it is practically impossible to study the dependence of properties of MCAs on a wide range of composition, which is the major bottleneck in conducting systematic studies on MCAs to seek and explore new physical properties. The crystalline structure of bulk MCAs strongly depends on composition and processing; thus such dependence would be much stronger in thin films as evidenced in AlCoCrCuFeNi alloys showing a variety of micrometer-scale structures in thin films.

Reactive sputtering is used for depositing nitride (e.g. Fe—Co—Ni—Cr—Cu—Al—Mn and Fe—Co—Ni—Cr—Cu—Al_{0.5}), oxide (e.g. AlxCoCrCuFeNi), and intermetallic multi-component alloys in the form of thin film, which is presumably because of the fact that SPU has flexible control on composition of thin films that contain multiple components. Many experiments indeed are done with synthesis techniques such as arc casting suitable for making bulk materials. Many studies also were done on samples deposited with reactive sputtering using targets that already contain desired elements with specific mole fraction, in other words, the dependence of properties of a HPA thin film on its composition is hardly studied. The crystalline structure of bulk multi-component alloys strongly depends on the chemical composition and processing; thus it is conceivable that such dependence would be much stronger in thin films as evidenced in AlCoCrCuFeNi alloys showing a variety of micrometer-scale structures in thin films. These micrometer-scale structures would act as detrimental structures that scatter charged particles and photons when active devices are envisioned; therefore, the current SAS invention is useful to deposit multi-component alloys in unique and well-controlled deposition environments conventional reactive SPU cannot provide.

Fundamental studies on magnetoelectric multiferroics (MFs), often made of complex oxides such as La₁₋ₓSrₓMnO₃ (LSMO), that possess both ferromagnetic and ferroelectric ground states have been attracting a large number of researchers. Deposition of such complex oxides has been demonstrated by various deposition techniques including reactive sputtering, laser molecular beam epitaxy, pulsed-laser deposition and chemical vapor deposition. Among various thin film deposition techniques, two deposition techniques, SPU and chemical vapor deposition (CVD) are positioned far away from each other in terms of the mechanism that mainly governs the evolution of thin films. In SPU, elemental constituents separately arriving at the surface of a substrate react with oxygen to form a thin film, in which case the deposition process is viewed as far-from-equilibrium. In contrast, in CVD, after mass transport though the boundary layer to a substrate completes, chemical reaction and subsequent formation of a thin film on the surface of a substrate proceed at near-equilibrium.

Sputtering has been used extensively to produce LSMO thin films while there have been only few demonstrations of the synthesis of LSMO thin films by CVD. This is primarily because the design of overall processes involved in sputtering is simple and sputtering does not require complicated chemicals as in CVD. One drawback of SPU, however, is the strong tendency to form multiple phases, which is not a desirable feature when a large number of devices based on MFs are fabricated and all of them are expected to have uniform characteristics. Furthermore, fine-tuning of an interface between two thin films is not trivial in SPU as elemental species arriving at the surface of a substrate have rather high kinetic energy. SPU of constituents out of the growing thin film itself is also a drawback. Apart from SPU, ALD appears to be an attractive route. With the advancement and acceptance of ALD in microelectronics, a wide range of precursors becomes available continuously. For instance, liquid precursors with appropriate vapor pressure are commercially available as La, Sr, Pr, and Mn sources. These precursors, combined with a reactive oxygen source such as ozone, can be used to produce, for example, LSMO thin films. ALD come with an advantage of being a low temperature deposition process.

Regarding SPU and ALD within the context of depositing MF thin films SAS is well-suited for depositing MF thin films in unique and well-controlled deposition environments that neither conventional reactive SPU nor ALD offer. In one embodiment, external electric fields are introduced to control the motion of charged particles present in a vapor phase as well as on the deposition surface to “energize” a SAS process environment without increasing the temperature of deposition environment.

According to the current invention, the single most important feature that differentiates SAS from either SUP or ALD is that SAS provides versatile deposition environments that cannot be established by SUP alone, ALD alone, or even SUP connected to ALD through vacuum (i.e. cluster tool) with superior control on both composition and thickness. The current invention enables precision of compositional and thickness to less than 1% mole fraction and less than 0.2 nm, respectively, where a monolayer of ABx compound is initially deposited by ALD with a stoichiometric composition x=2. If a NSC ABx (x<2) thin film is desired, then a certain amount of “excess” A element is deposited by SPU to drive AB2 into AB2−y. Alternatively, if a NSC ABx (x>2) thin film is required, then a certain amount of “excess” B element is added by SPU to drive AB2 into AB2+y. SAS allows “in-situ” tuning of composition without substantially altering a given thickness, which cannot be done by either SPU or ALD.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example two separate deposition chambers separately configured for either ALD or SPU and connected through a gate valve through which a sample is transferred by means of, for instance, a transfer rot. Further, a deposition chamber having a substrate stage that can be raised toward and lowered away from sputtering guns. A further variation includes a deposition chamber in which a substrate holder faces downward and sputtering guns point upward. Another variation includes a deposition chamber in which a substrate holder faces sideway and sputtering guns also point sideways.

All such variations are considered to be within the scope and spirit of the present invention as defined by the following claims and their legal equivalents.

What is claimed:

1) A single deposition chamber apparatus comprising a first deposition mode and a second deposition mode, wherein said deposition modes are configured to alternate, wherein said single deposition chamber comprises:
a) a substrate holder;
b) a retractable sputter gun;
c) a gate valve;
d) an output port;
e) a retractable chamber separator;
f) a gas input port;
g) a gas output port; and
h) an electron cyclotron resonance plasma source;
wherein said retractable chamber separator is configured to selectively segment said deposition chamber to alternate between said first deposition mode and said second deposition mode, wherein said second deposition comprises said substrate holder, said gas input port, said gas output port and said electron cyclotron resonance plasma source.

2) The single deposition chamber apparatus of claim 1, wherein said retractable sputter gun is configured to retract from said deposition chamber when said retractable chamber separator is deployed to establish said first deposition mode, wherein said retractable sputter gun is configured to deploy into said single deposition chamber when said retractable chamber separator is retracted from said single deposition chamber.

3) The single deposition chamber apparatus of claim 2, wherein said gate valve is configured to close when said sputter gun is configured to retract from said single deposition chamber, where said gate valve is configured to open when said sputter gun is configured to deploy into said single deposition chamber.

4) The single deposition chamber apparatus of claim 2, wherein said first deposition mode further comprises a sputter gun shutter, wherein said sputter gun shutter is configured to close when said sputter gun is retracted, wherein said sputter gun is isolated from said single deposition chamber.

5) The single deposition chamber apparatus of claim 1, wherein said gas input port is coupled with said electron cyclotron resonance plasma source.

6) The single deposition chamber apparatus of claim 1, wherein said deposition mode is configured for a deposition mode selected from the group consisting of chemical vapor deposition, atomic layer deposition, and sputter deposition.

7) The single deposition chamber apparatus of claim 1, wherein said second deposition mode is configured for atomic layer deposition.

8) The single deposition chamber apparatus of claim 1, wherein said substrate holder comprises a DC source, an AC source, or DC source and an AC source.

9) The single deposition chamber apparatus of claim 1, wherein said substrate holder is configured to rotate.

10) The single deposition chamber apparatus of claim 1, wherein said substrate holder is configured to translate a substrate within said single deposition chamber, and configured to rotate.
